(19) United States
(12) Patent Application Publication
(10) Pub. No.: US 2008/0283872 A1
(43) Pub. Date: Nov. 20, 2008

(54) Variable path wiring cell, semiconductor integrated circuit designing method thereof, and forming method of variable path wiring cell

(76) Inventors: Junji Kubo, Shiga (JP); Atsushi Yamamoto, Hyogo (JP); Shoji Takaoka, Osaka (JP)

Correspondence Address: MCDERMOTT WILL & EMERY LLP, 600 13TH STREET, NW, WASHINGTON, DC, 20005-3096, US

(21) Appl. No.: 11/898,696

(22) Filed: Sep. 14, 2007

(30) Foreign Application Priority Data
Sep. 21, 2006 (JP) 2006-255440

(51) Int. Cl. H01L 23/525; G06F 17/50; H01L 21/4763

(52) U.S. Cl. 257/209; 716/10; 438/618; 257/E23.146; 257/E21.495

(57) ABSTRACT

Provided are a first wiring layer where each of the first, second internally present wirings can be selectively connected to the first and the second externally extended wirings, and a second wiring layer that has substantially the same structure as that of the first wiring layer. There is further provided an interlayer contact layer which arbitrarily connects one of the first and the second internally present wirings on the first wiring layer to one of the first, second internally present wirings on the second wiring layer, and connects the remainder of the first and the second internally present wirings on the first wiring layer to the remainder of the first and the second internally present wirings on the second wiring layer.

### BACKGROUND OF THE INVENTION

1. Field of the Invention

The present invention relates to a layout structure and a layout designing method, which are used for correcting an internal circuit of a semiconductor integrated circuit.

2. Description of the Related Art

Normally, semiconductor integrated circuits are shipped with identification numbers attached thereto such as type codes for identifying the type of the chips, manufacture code numbers with which the manufacture time can be specified, etc. Each of the semiconductor integrated circuits is also supplied with a version code indicating that the circuit structure thereof is slightly different because of a revision even if the product type is the same.

Conventionally, in revising a chip, it is necessary to alter the structure of a version managing register as a mask ROM in order to revise a version code, in addition to the alternation to the circuit part that requires a correction. In a case where a change is made to even a single mask for correcting a function, it is also necessary to correct other masks that are related to the formation of the version managing register. However, the cost for the masks has been increasing, so that it is required to achieve corrections with the fewest number of masks.

As a method for revising the version code of a semiconductor integrated circuit only with a change of the minimum number of masks, there has been proposed a method shown in FIG. 21, which uses an exclusive OR circuit (EXOR) that has input terminals in numbers corresponding to necessary wiring layers in accordance with a process. This is disclosed in Japanese Published Patent Document (Japanese Unexamined Patent Publication No. 2003-23091), for example. A version managing circuit 10 used in this method comprises mask revision state output circuits M₁-Mₙ and an EXOR circuit 20. The mask revision state output circuits M₁-Mₙ are reformed by only a change of a single mask, and they selectively output a logic level “H” or “L”. For example, the mask revision state output circuit M₁ outputs one of the logic levels in accordance with a change (element isolation forming state) of a mask pattern for forming an element isolation region of a transistor. The EXOR circuit 20 performs EXOR operations on output values that are outputted from each of the mask revision state output circuits M₁-Mₙ, and outputs the results thereof as register values. With the version managing circuit 10, it is possible to rewrite the version code by the revision of only a single mask.

On the other hand, it is necessary in the method shown in FIG. 21 to increase the size of the cell when the number of wiring layers is increased because of development in the process. Therefore, there has been proposed a method shown in FIG. 22A and FIG. 22B for making a correction only with wirings without using the cell. This method is disclosed in Japanese Published Patent Document (Japanese Unexamined Patent Publication No. H8-181068), for example.

FIG. 22A shows a circuit 30 before being corrected. An externally extended wiring E1 connected to an input terminal I1 and an externally extended wiring F1 connected to an output terminal O1 are connected via a connection wiring J1 and vias V. An externally extended wiring E2 connected to an input terminal I2 and an externally extended wiring F2 connected to an output terminal O2 are connected via a connection wiring J2 and vias V. The externally extended wirings E1 and E2 and the externally extended wirings F1, F2 exist on a first wiring layer, while the connection wirings J1, J2 exist on a second wiring layer.

FIG. 22B shows a circuit 40 after being corrected. The externally extended wiring E1 connected to the input terminal I1 and the externally extended wiring F2 connected to the output terminal O2 are connected via the connection wiring j1 and the vias V. Further, the externally extended wiring E2 connected to the input terminal I2 and the externally extended wiring F1 connected to the output terminal O1 are connected via a U-shaped connection wiring j2 and the vias V. The changed points are shown in FIG. 22C. The connection wirings J1 and J2 are eliminated. With this method, it is possible to rewrite the version code with the revision of only a single mask.

However, for a circuit correction of a semiconductor integrated circuit performed through such mask pattern correction, it is necessary to correct a great number of wiring layers in order to execute switching of signals. In doing so, the number of masks to be corrected and the number of correcting steps are increased, which becomes the factors responsible for increasing the manufacturing cost of the semiconductor integrated circuits.

### SUMMARY OF THE INVENTION

The main object of the present invention therefore is to provide a variable path wiring cell that is capable of reducing the number of masks to be corrected when executing a correction of a circuit in a semiconductor integrated circuit.

A variable path wiring cell according to the present invention comprises:
a first wiring layer which comprises a first and a second internally present wirings provided inside the cell as well as a first and a second externally extended wirings that are provided with an internally present part within the cell and an externally extended part extending towards an outer side of the cell, wherein each of the first and second internally present wirings can be selectively connected to the first and second externally extended wirings;
a second wiring layer which comprises substantially the same first and second internally present wirings and substantially the same first and second externally extended wirings as those of the first wiring layer, while having a different wiring longitudinal direction from that of the first wiring layer and being disposed in a manner opposite to the first wiring layer; and
an interlayer contact layer which arbitrarily connects one of the first and the second internally present wirings on the first wiring layer to one of the first, second internally present wirings on the second wiring layer, and connects the remainder of the first and the second internally present wirings on the first wiring layer to the remainder of the first and the second internally present wirings on the second wiring layer.

With this structure, under the state where the first internally present wiring (e1) is connected to the first externally extended wiring (E1) on the first wiring layer, the second internally present wiring (e2) is connected to the second externally extended wiring (E2). Inversely, under the state where the first internally present wiring (e1) is connected to the second externally extended wiring (E2) on the first wiring layer, the second internally present wiring (e2) is connected to the first externally extended wiring (E1). This is an alteration of the paths on the first wiring layer. The second wiring layer has the same alternation of the paths. Further, under the state where the first internally present wiring (e1) of the first wiring layer is connected to the first internally present wiring (f1) of the second wiring layer, the second internally present wiring (e2) of the first wiring layer is connected to the second internally present wiring (f2) of the second wiring layer. Inversely, under the state where the first internally present wiring (e1) of the first wiring layer is connected to the second internally present wiring (f2) of the second wiring layer, the second internally present wiring (e2) of the first wiring layer is connected to the first internally present wiring (f1) of the second wiring layer. This is an alteration of the paths on the interlayer contact layer.

As described above, with the variable path wiring cell of the present invention, it is possible to switch two arbitrary power supply wirings or two signal wirings between the first wiring layer and the second wiring layer of the semiconductor integrated circuit only through a correction in a single mask of the first wiring layer, the second wiring layer, or the interlayer contact layer. That is, the number of the masks to be corrected can be reduced when correcting wiring switch between the first wiring layer and the second wiring layer.

Further, there is such a form that a semiconductor integrated circuit of the present invention comprises:
a version code register; and
the variable path wiring cell of the present invention, wherein
there are a plurality of the variable path wiring cells being provided, and the variable path wiring cells are connected to the version code register.

This structure makes it possible to achieve management of the revised information of the semiconductor integrated circuit through managing a version code by correcting the mask in the wiring forming step or by correcting the mask in the contact hole forming step, with the use of the variable path wiring cell provided in a free space of the wiring inside the semiconductor integrated circuit.

A semiconductor integrated circuit designing method of the present invention is a semiconductor integrated circuit designing method which applies the variable path wiring cell of the present invention to a dummy cell that is disposed within a semiconductor integrated circuit. The method comprises:
a step of detecting the dummy cell;
a step of disposing the variable path wiring cell in a vicinity of the dummy cell; and
a step of connecting the variable path wiring cell to the dummy cell.

With this circuit designing method, through applying the variable path wiring cell to the dummy cell that is provided in advance for easily correcting the circuit, it is possible to achieve a correction of the circuit between the power supply wiring and the signal wiring on the first wiring layer and the dummy cell on the second wiring layer by simply correcting one of the masks in any of the first, second wiring layer forming step of the wiring forming step and the contact hole forming step.

Furthermore, a semiconductor integrated circuit designing method of the present invention is a semiconductor integrated circuit designing method which applies the variable path wiring cell of the present invention to an input/output terminal. The method comprises:
a step of detecting the input/output terminal;
a step of cutting a connection between the input/output terminal and a signal wiring that is connected to the input/output terminal;
a step of disposing the variable path wiring cell in the vicinity of the input/output terminal; and
a step of connecting the input/output terminal to the cut out signal wiring via the variable path wiring cell.

With this circuit designing method, in correcting the circuit through applying the variable path wiring cell to the input/output terminal, it is possible to achieve a correction of the circuit between the signal wiring of the first wiring layer and the input/output terminal of the second wiring layer by simply correcting one of the masks in any of the first, second wiring layer forming step of the wiring forming step and the contact hole forming step.

Further, a semiconductor integrated circuit designing method of the present invention is a semiconductor integrated circuit designing method which applies the variable path wiring cell of the present invention to an input/output terminal and a delay cell. The method comprises:
a step of detecting the input/output terminal;
a step of cutting a connection between the input/output terminal and a signal wiring that is connected to the input/output terminal;
a step of disposing the variable path wiring cell and the delay cell in the vicinity of the input/output terminal;
a step of connecting the cut out signal wiring to an input terminal of the delay cell; and
a step of connecting the variable path wring cell to the input/output terminal and an output terminal of the delay cell.

This circuit designing method makes it possible to correct the delay in the input/output terminal of the semiconductor integrated circuit by correcting the mask in the wiring forming step or by correcting the mask in the contact hole forming step, through applying the variable path wiring cell to the input/output terminal and the delay cell.

Furthermore, a semiconductor integrated circuit designing method of the present invention is a semiconductor integrated circuit designing method which applies the variable path wiring cell of the present invention to an input/output terminal and a driving cell. The method comprises:
a step of detecting the input/output terminal;
a step of cutting a connection between the input/output terminal and a signal wiring that is connected to the input/output terminal;
a step of disposing the variable path wiring cell and the driving cell in the vicinity of the input/output terminal; and
a step of connecting the cut out signal wiring to an input terminal of the driving cell; and
a step of connecting the variable path wiring cell to the input/output terminal and an output terminal of the driving cell.

This circuit designing method makes it possible to correct the driving capacity of the input/output terminal of the semiconductor integrated circuit by correcting the mask in the wiring forming step or by correcting the mask in the contact hole forming step, through applying the variable path wiring cell and the driving cell to the input/output terminal.

Further, a semiconductor integrated circuit designing method of the present invention is a semiconductor integrated circuit designing method which applies the variable path wiring cell of the present invention having a pair of terminals to a dummy flip-flop having a clock terminal. The method comprises:
a step of detecting the dummy flip-flop;
a step of disposing the variable path wiring cell in the vicinity of the dummy flip-flop;
a step of connecting the variable path wiring cell to the clock terminal; and
a step of connecting one of the terminals of the variable path wiring cell to a power supply or a ground.

When the semiconductor integrated circuit is subjected to a correction made by a change in the mask pattern in the wiring forming step or the contact hole forming step, there is a change in the amount of the delay generated in the clock wiring. However, through connecting the clock pin of the dummy flip-flop and the output of the clock buffer to the variable path wiring cell, the amount of the change in the delay mentioned above can be reduced.

Further, a variable path wiring cell forming method of the present invention comprises:
a step of forming a k-th wiring layer (m≦k≦n−1, where m and n are integers of 1 or larger (n−m≧2)), which comprises a first and a second internally present wirings provided inside the cell as well as a first and a second externally extended wirings that are provided with an internally present part within the cell and an externally extended part extending towards an outer side of the cell, wherein each of the first and second internally present wirings can be selectively connected to the first and second externally extended wirings,
a step of forming a (k+1)th wiring layer which comprises substantially the same first and second internally present wirings and substantially the same first and second externally extended wirings as those of the k-th wiring layer, while having a different wiring longitudinal direction from that of the k-th wiring layer and being disposed in a manner opposite to the k-th wiring layer;
a step of forming an interlayer contact layer which arbitrarily connects one of the first and the second internally present wirings on the k-th wiring layer to one of the first, second internally present wirings on the (k+1)th wiring layer, and connects the remainder of the first and the second internally present wirings on the k-th wiring layer to the remainder of the first and the second internally present wirings on the (k+1)th layer; and
a step of repeating the steps described above to a (n−1)th layer by replacing “k” with “(k+1)”.

This makes it possible to correct the circuit in the semiconductor integrated circuit by correcting the mask in the wiring forming step or by correcting the mask in the contact hole forming step, through constituting the variable path wiring cell in three layers or more.

The present invention uses the variable path wiring cell that is capable of switching the signal wirings with only a change in one of the masks, when executing correction of the circuit in the semiconductor integrated circuit. The variable path wiring cell has no connection with the gate, so that it can be disposed in any of free areas as long as the area is within the semiconductor integrated circuit. Therefore, it is possible to reduce the number of steps for correcting the circuit, and to reduce the cost of the masks and the number of steps involved in correcting the circuit in the semiconductor integrated circuit.

The technique of the present invention is useful for correcting the signal wirings between the internal circuits in the semiconductor integrated circuit.

### BRIEF DESCRIPTION OF THE DRAWINGS

Other objects of the present invention will become clear from the following description of the preferred embodiments and be specified in the appended claims. Those skilled in the art will find out many advantages of the present invention other than those described in this specification through the implementation of the present invention.

FIG. 1 is a schematic block diagram of a variable path wiring cell according to a first embodiment of the present invention;

FIG. 2 is a layout top plan view for showing a structure of the variable path wiring cell according to the first embodiment of the present invention;

FIG. 3 is a first illustration for showing an example of a connecting relation between the terminals within the variable path wiring cell according to the first embodiment of the present invention;

FIG. 4 is a second illustration for showing an example of a connecting relation between the terminals within the variable path wiring cell according to the first embodiment of the present invention;

FIG. 5 is a third illustration for showing an example of a connecting relation between the terminals within the variable path wiring cell according to the first embodiment of the present invention;

FIG. 6 is a schematic block diagram of a version code managing circuit according to the first embodiment of the present invention;

FIG. 7 is a flowchart for showing a procedure of a semiconductor integrated circuit designing method according to a second embodiment of the present invention;

FIGS. 8A and 8B are illustrations for showing schematic structures of connection forms between a dummy cell and a variable path wiring cell according to the second embodiment of the present invention;

FIG. 9 is a flowchart for showing a procedure of a semiconductor integrated circuit designing method according to a third embodiment of the present invention;

FIGS. 10A and 10B are illustrations for showing schematic structures of connection forms between input/output terminals and a variable path wiring cell according to the third embodiment of the present invention;

FIG. 11 is a flowchart for showing a procedure of a semiconductor integrated circuit designing method according to a fourth embodiment of the present invention;

FIGS. 12A and 12B are illustrations for showing schematic structures of connection forms between an input/output terminal, a delay cell, and a variable path wiring cell according to the fourth embodiment of the present invention;

FIG. 13 is a flowchart for showing a procedure of a semiconductor integrated circuit designing method according to a fifth embodiment of the present invention;

FIGS. 14A and 14B are illustrations for showing schematic structures of connection forms between an input/output terminal, driving cells, and a variable path wiring cell according to the fifth embodiment of the present invention;

FIG. 15 is a flowchart for showing a procedure of a semiconductor integrated circuit designing method according to a sixth embodiment of the present invention;

FIGS. 16A and 16B are illustrations for showing schematic structures of connection forms between a dummy flip-flop and a variable path wiring cell according to the sixth embodiment of the present invention;

FIG. 17 is a schematic plan view before the sixth embodiment of the present invention is applied;

FIG. 18 is a schematic plan view after the sixth embodiment of the present invention is applied;

FIG. 19 is a layout top plan view for showing a structure of a variable path wiring cell according to the seventh embodiment of the present invention;

FIG. 20 is a layout top plan view for showing a structure of the variable path wiring cell according to the seventh embodiment of the present invention;

FIG. 21 is a schematic block diagram of a version managing circuit according to a conventional technique; and

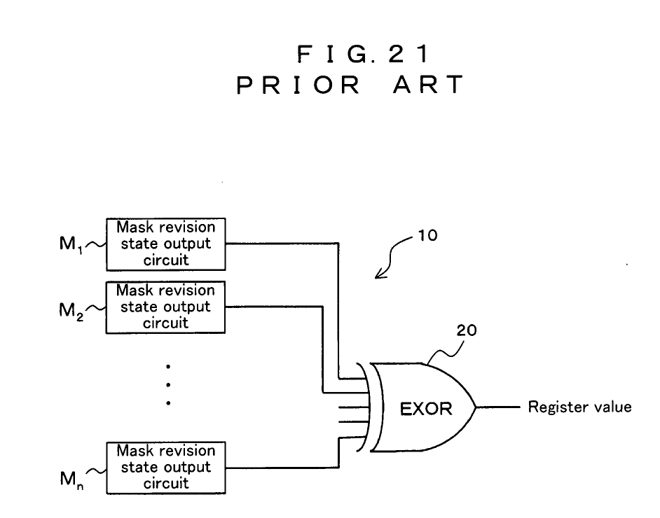

FIGS. 22A-22C show an example of switching signals with the wirings of the conventional technique.

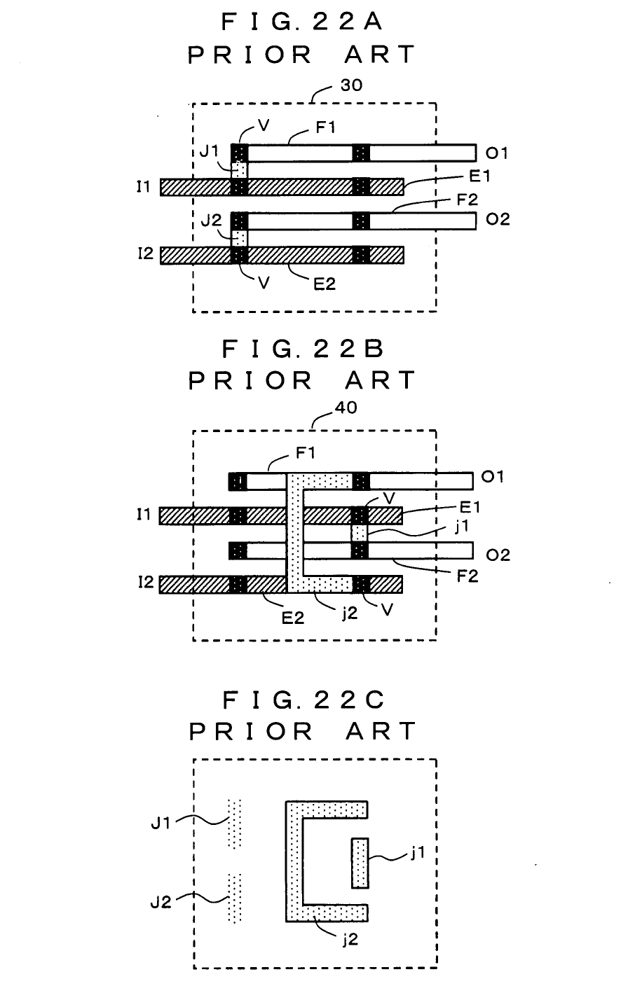

### DETAILED DESCRIPTION OF THE INVENTION

Hereunder, embodiments of a semiconductor integrated circuit designing method according to the present invention will be described in detail by referring to the accompanying drawings.

### First Embodiment

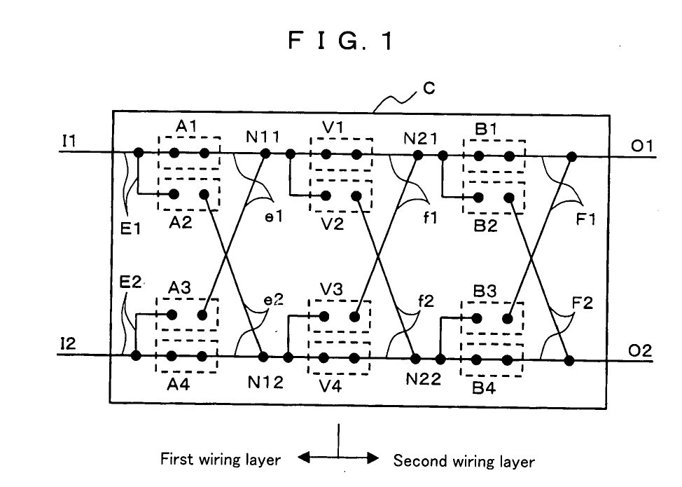

FIG. 1 is a schematic block diagram of a variable path wiring cell C according to a first embodiment of the present invention. The variable path wiring cell C changes the connecting relation (paths) between input terminals and output terminals through changing one of a mask pattern that is formed in a wiring forming step and a mask pattern that is formed in a contact hole forming step. This variable path wiring cell C comprises:
a wiring area A1 where a connection state between an input terminal I1 and an intermediate node N11 is determined;
a wiring area A2 where a connection state between the input terminal I1 and an intermediate node N12 is determined;
a wiring area A3 where a connection state between an input terminal I2 and the intermediate node N11 is determined;
a wiring area A4 where a connection state between the input terminal I2 and the intermediate node N12 is determined;
a wiring area V1 where a connection state between the intermediate node N11 and an intermediate node N21 is determined;
a wiring area V2 where a connection state between the intermediate node N11 and an intermediate node N22 is determined;
a wiring area V3 where a connection state between the intermediate node N12 and an intermediate node N21 is determined;
a wiring area V4 where a connection state between the intermediate node N12 and an intermediate node N22 is determined;
a wiring area B1 where a connection state between the intermediate node N21 and an output terminal O1 is determined;
a wiring area B2 where a connection state between the intermediate node N21 and an output terminal O2 is determined;
a wiring area B3 where a connection state between the intermediate node N22 and the output terminal O1 is determined; and
a wiring area B4 where a connection state between the intermediate node N22 and an output terminal O2 is determined. In FIG. 1, the left-half part is the first wiring layer, and the right-half part is the second wiring layer.

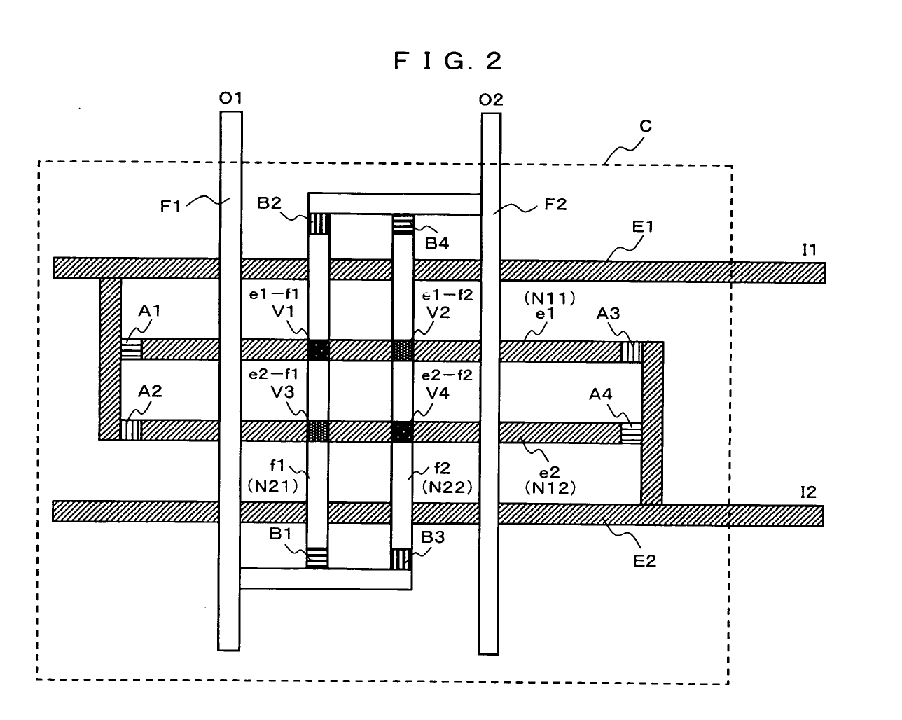

FIG. 2 is a layout top plan view for describing the structure of the variable path wiring cell C that is shown in FIG. 1. This variable path wiring cell C comprises: the first wiring layer; the second wiring layer disposed in a manner above and opposite to the first wiring layer; and an interlayer contact layer for connecting the first wiring layer and the second wiring layer.

A first internally present wiring e1 and a second internally present wiring e2, which are in parallel with each other and extended in a horizontal direction, are provided on the first wiring layer. A first externally extended wiring E1 and a second externally extended wiring E2 are provided on the outer side of the first wiring layer. The internally present wirings e1 and e2 are provided only inside the variable path wiring cell C. The externally extended wirings E1 and E2 have a part provided inside the variable path wiring cell C, and a part extended to the outer side of the variable path wiring cell C. The externally extended parts of the externally extended wirings E1 and E2 serve as the input terminals I1 and I2. The externally extended wirings E1 and E2 are formed in a T-shape, which comprise a relatively long main part and a branch part extended at the right angle from the main part. Each of the first, second internally present wirings e1, e2 can be selectively connected to the first and the second externally extended wirings E1 and E2. It is possible to selectively connect/not to connect the internally present wirings e1, e2 and the externally extended wirings E1, E2 electrically on the same layer based on whether forming or not forming a wiring pattern on wiring areas A1-A4 as necessary. The first and second internally present wirings e1 and e2 can be selectively connected to the first externally extended wiring E1 in each of the wiring areas A1 and A2 on the first wiring layer. Further, the first and second internally present wirings e1 and e2 can be selectively connected to the second externally extended wiring E2 in each of the wiring areas A3 and A4. That is, under the state where the first internally present wiring e1 is connected to the first externally extended wiring E1 via the wiring area A1, the second internally present wiring e2 is connected to the second externally extended wiring E2 via the wiring area A4. Inversely, under the state where the first internally present wiring e1 is connected to the second externally extended wiring E2 via the wiring area A3, the second internally present wiring e2 is connected to the first externally extended wiring E1 via the wiring area A2. The above is an alteration of the paths on the first wiring layer.

The second wiring layer has the same or similar pattern as that of the first wiring layer. Further, the second wiring layer is arranged in a manner opposing to and with a 90-degree shift in a longitudinal direction with respect to the first wiring layer. On the second wiring layer, a first internally present wiring f1 and a second internally present wiring f2 provided in a vertical direction in FIG. 2 are arranged in parallel with each other. The first, second externally extended wirings F1, F2 are provided on the outer side of the layout of the first and the second internally present wirings f1, f2. The internally present wirings f1 and f2 are provided only inside the cell. The externally extended wirings F1 and F2 have a part provided inside the cell, and a part extended to the outer side of the cell (externally extended part). The externally extended parts of the externally extended wirings F1 and F2 serve as the output terminals O1 and O2. The externally extended wirings F1 and F2 are formed in a T-shape, which comprise a relatively long main part and a branch part extended at the right angle from the main part. Each of the first, second internally present wirings f1, f2 can be selectively connected to the first and the second externally extended wirings F1, F2. It is possible for the internally present wirings f1, f2 and the externally extended wirings F1, F2 to select either an electrically connected state or an electrically non-connected state on the same layer based on forming a wiring pattern on wiring areas B1-B4 as necessary. The first and second internally present wirings f1 and f2 can select either a connected state or a non-connected state with respect to the first externally extended wiring F1 in each of the wiring areas B1 and B3 on the second wiring layer. Further, the first and second internally present wirings f1 and f2 can be selectively connected to the second externally extended wiring F2 in each of the wiring areas B2 and B4. That is, under the state where the first internally present wiring f1 is connected to the first externally extended wiring F1 via the wiring area B1, the second internally present wiring f2 is connected to the second externally extended wiring F2 via the wiring area B4. Inversely, under the state where the first internally present wiring f1 is connected to the second externally extended wiring F2 via the wiring area B2, the second internally present wiring f2 is connected to the first externally extended wiring F1 via the wiring area B3. The above is an alteration of the paths on the second-wiring layer.

The variable path wiring cell C comprises an interlayer contact layer which connects one of the first and second internally present wirings on the first wiring layer to one of the first and second internally present wirings on the second wiring layer, and connects the remaining one of the first and second internally present wirings on the first wiring layer to the remaining one of the first and second internally present wirings on the second wiring layer. The interlayer contact layer is provided between the first wiring layer and the second wiring layer, which are facing each other. In the interlayer contact layer, a contact wiring area V1 is provided between the internally present wiring e1 and the internally present wiring f1, a contact wiring area V2 is provided between the internally present wiring e1 and the internally present wiring f2, a contact wiring area V3 is provided between the internally present wiring e2 and the internally present wiring f1, and a contact wiring area V4 is provided between the internally present wiring e2 and the internally present wiring f2. It is possible to selectively connect each of the first and second internally present wirings e1, e2 and the first and second internally present wirings f1, f2 electrically on the same layer through forming a wiring pattern on the contact wiring areas V1-V4 as necessary. Under the state where the first internally present wiring e1 is connected to the first internally present wiring f1 via the contact wiring area V1, the second internally present wiring e2 is connected to the second internally present wiring f2 via the contact wiring area V4. Inversely, under the state where the first internally present wiring e1 is connected to the second internally present wiring f2 via the contact wiring area V2, the second internally present wiring e2 is connected to the first internally present wiring f1 via the contact wiring area V3.

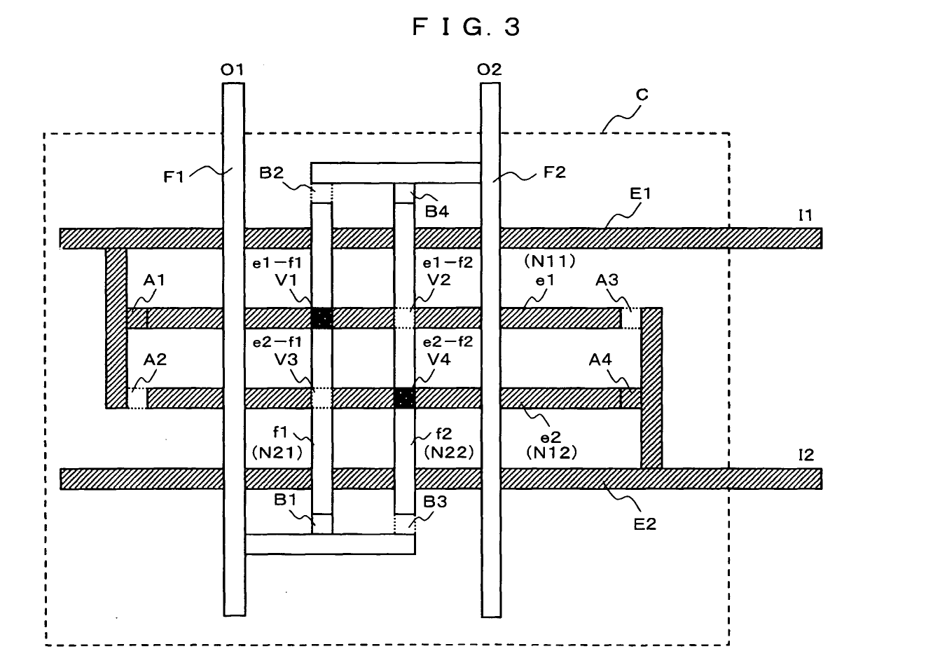

Hereinafter, manufacturing steps of the variable path wiring cell C will be described by referring to FIG. 3.
First, a mask pattern from which the wiring areas A2 and A3 are eliminated is prepared as a mask pattern for a wiring forming step for the first wiring layer, and the first wiring layer is formed by using the mask pattern.
Further, a mask pattern from which the wiring areas B2 and B3 are eliminated is prepared as a mask pattern for a wiring forming step for the second wiring layer, and the second wiring layer is formed by using the mask pattern.
Furthermore, a mask pattern where the contact wiring areas V2 and V3 are masked is prepared as a mask pattern for a contact hole forming step, and a contact hole is formed by using the mask pattern.

With this, the connection states become as follows. That is:
the wiring areas A1 and A4 are connected;
the wiring areas A2 and A3 are not connected;
the contact wiring areas V1 and V4 are connected;
the contact wiring areas V2 and V3 are not connected;
the wiring areas B1 and B4 are connected; and
the wiring areas B2 and B3 are not connected.

In the variable path wiring cell C formed through the above-described steps, the input terminal I1 and the output terminal O1 are electrically connected (I1-E1-A1-e1-V1-f1-B1-F1-O1), and the input terminal I2 and the output terminal O2 are electrically connected (I2-E2-A4-e2-V4-f2-B4-F2-O2).

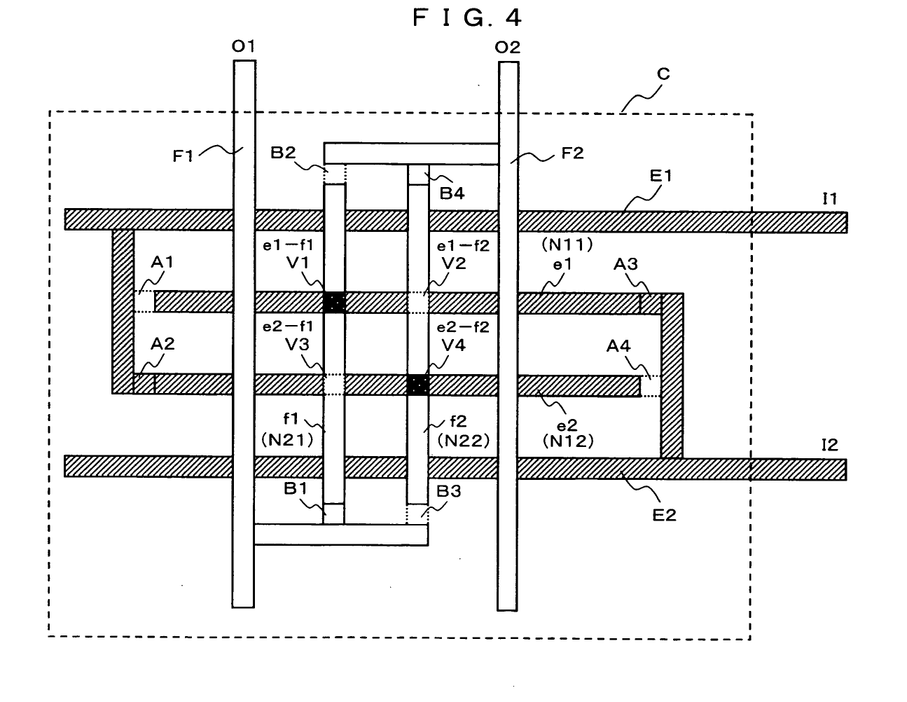

Described next by referring to FIG. 4 is the fact that the variable path wiring cell C shown in FIG. 3 is capable of changing the connecting relation between the input terminals and the output terminals only with a correction of the first wiring layer. A mask pattern from which the wiring areas A1 and A4 are eliminated is prepared as the mask pattern for the wiring forming step for the first wiring layer, and the first wiring layer is formed by using the mask pattern. With this, the wiring areas A2 and A3 are connected, and the wiring areas A1 and A4 are not connected. In the variable path wiring cell C formed by using this mask pattern, the input terminal I1 and the output terminal O2 are electrically connected (I1-E1-A2-e2-V4-f2-B4-F2-O2), and the input terminal I2 and the output terminal O1 are electrically connected (I2-E2-A3-e1-V1-f1-B1-F1-O1).

The second wiring layer is also formed with the same mask pattern as that of the first wiring layer. Therefore, it is also possible to change the connecting relation between the input terminals and the output terminals only with a correction of the second wiring layer ((I1-E1-A1-e1-V1-f1-B2-F2-O2), (I2-E2-A4-e2-V4-f2-B3-F1-O1)).

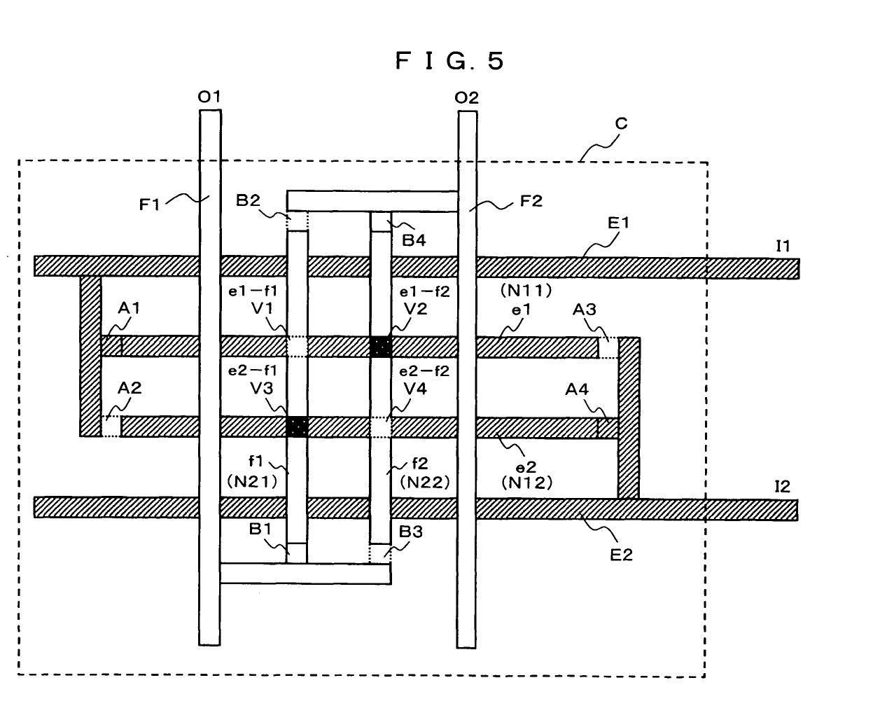

Next, described by referring to FIG. 5 is the fact that the variable path wiring cell C is capable of changing the connecting relation between the input terminals and the output terminals only with a correction of a contact hole which electrically connects the first wiring layer and the second wiring layer. A mask pattern from which the contact wiring areas V1 and V4 are eliminated is prepared as a mask pattern for a contact hole forming step, and a contact hole is formed by using the mask pattern. With this, the contact wiring areas V2 and V3 become connected, and the contact wiring areas V1 and V4 are not connected. In the variable path wiring cell C formed by using this mask pattern, the input terminal I1 and the output terminal O2 are electrically connected (I1-E1-A1-e1-V2-f2-B4-F2-O2), and the input terminal I2 and the output terminal O1 are electrically connected (I2-E2-A4-e2-V3-f1-B1-F1-O1).

With the above-described structure, it becomes possible to switch the path that connects the input terminal I1 and the output terminal O1 and the path that connects the input terminal I1 and the output terminal O2 by correcting one layer of the first wiring layer, the second wiring layer, and the contact hole layer in the internal structure of the variable path wiring cell C. This makes it possible to deal with a switching correction of the signals only by a correction of a single mask, even when performing a switching correction of the signals of the two connected wirings.

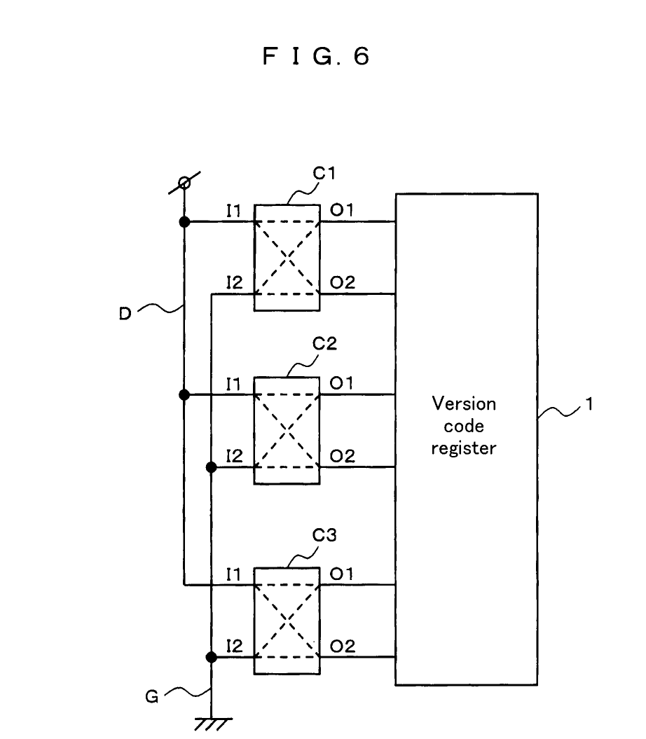

FIG. 6 is a schematic block diagram of a version code managing circuit according to the first embodiment of the present invention. Reference numerals C1, C2, and C3 are variable path wiring cells. A power supply wiring D and a ground wiring G are connected to the input terminal of the first wiring layer of each of the variable path wiring cells C1, C2, and C3, and the output terminal of the second wiring layer of each of the variable path wiring cells C1, C2, and C3 is connected to a version code managing register 1.

With the above-described structure, values inputted to the version code managing register when performing various kinds of corrections in the semiconductor integrated circuit can be changed through changing the internal structures of the variable path wiring cells C1, C2, and C3.

### Second Embodiment

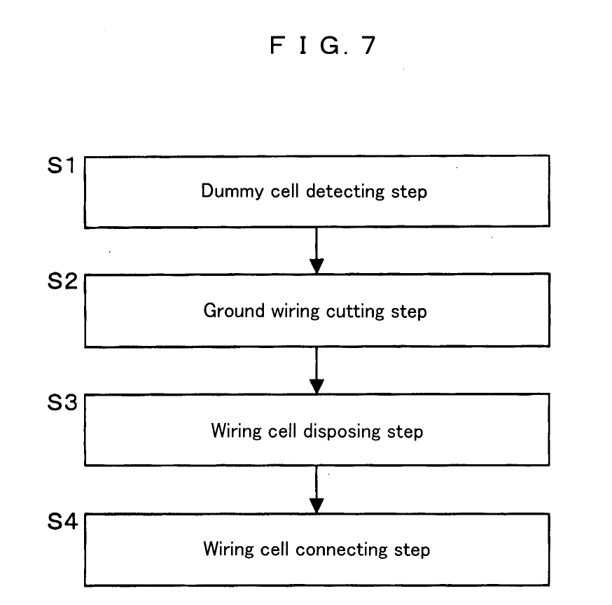

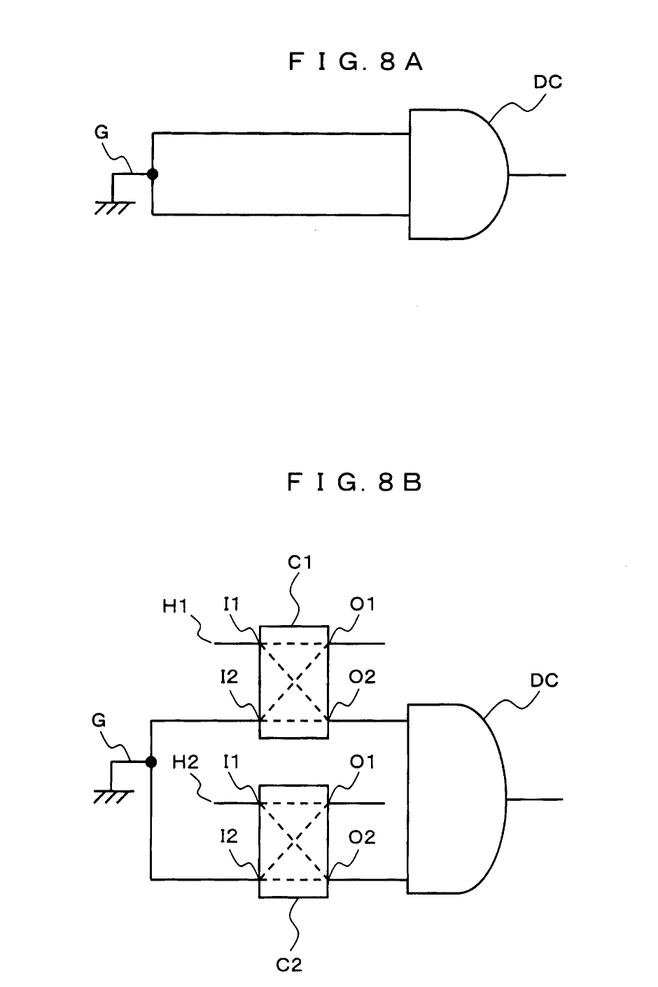

Next, a semiconductor integrated circuit designing method according to a second embodiment of the present invention will be described. FIG. 7 is a flowchart for showing a procedure of the semiconductor integrated circuit designing method according to the second embodiment. FIG. 8A and FIG. 8B are illustrations for showing a specific structure of a semiconductor integrated circuit fabricated through this designing method. In FIG. 7, reference numeral S1 is a dummy cell detecting step, S2 is a ground wiring cutting step, S3 is a wiring cell disposing step, and S4 is a wiring cell connecting step.

First, in the dummy cell detecting step S1, a dummy cell DC disposed within the semiconductor integrated circuit is detected. Then, in the ground wiring cutting step S2, an input terminal of the dummy cell DC and the ground wiring G connected to that input terminal is cut out. Thereafter, in the wiring cell disposing step S3, the variable path wiring cells C are disposed in the vicinity of the dummy cell DC. Then, in the wiring cell connecting step S4, a terminal on the first wiring layer of the variable path wiring cell C is connected to the input terminal of the dummy cell DC, and one of a pair of terminals on the second wiring layer of the variable path wiring cell C is connected to the ground wiring G.

FIG. 8A is a circuit structure before the variable path wiring cells C are inserted, and FIG. 8B is a circuit structure after the variable path wiring cells C are inserted. In FIG. 8A and FIG. 8B, reference symbol DC is a dummy cell, G is a ground wiring, and C1, C2 are variable path wiring cells.

The variable path wiring cells C1 and C2 comprise a pair of input terminals I1, I2, and a pair of output terminals O1, O2, wherein the input terminal I1 and the output terminal O1 are connected in parallel, and the input terminal I2 and the output terminal O2 are connected in parallel.

Further, the variable path wiring cells C1 and C2 are capable of switching the two connection states, i.e. a parallel connection state where the input terminal I1 is connected to the output terminal O1 within the cell, while the input terminal I2 is connected to the output terminal O2 within the cell, and a cross connection state where the input terminal I1 is connected to the output terminal O2 within the cell, while the input terminal I2 is connected to the output terminal O1 within the cell.

Hereinafter, switching of the connection states will be described in detail. First, when the dummy cell DC is detected, the ground wiring G that is connected to the detected dummy cell is cut out from the dummy cell. Then, the variable path wiring cells C1 and C2 are disposed in the vicinity of the dummy cell DC. Thereafter, the input terminals I2, I2 of the variable path wiring cells C1, C2 are connected to the cut out ground wiring G. Then, the output terminals O2, O2 of the variable path wiring cells C1, C2 are connected to each input terminal of the dummy cell DC.

With the use of the variable path wiring cells C capable of changing the internal structure, it is possible with the embodiment to switch the two connection states, i.e. a state where one of the input terminals of the dummy cell DC is connected to the ground wiring G via the input terminal I2 of the variable path wiring cell C1, and a state where one of the input terminals of the dummy cell DC is connected to a signal wiring H1 via the input terminal I1 of the variable path wiring cell C1. Apart from the above, it is also possible to switch the two connection states, i.e. a state where the other input terminal of the dummy cell DC is connected to the ground wiring G via the input terminal I2 of the variable path wiring cell C2, and a state where the other input terminal of the dummy cell DC is connected to a signal wiring H2 via the input terminal I1 of the variable path wiring cell C2.

As described above, through applying the variable path wiring cells C1, C2 to the dummy cell DC in the semiconductor integrated circuit, it is possible with the embodiment to achieve a correction of a circuit that is provided between the power supply wiring/signal wiring on the first wiring layer and the dummy cell DC on the second wiring layer by simply correcting one of the masks in the first and the second wiring layer forming step of the wiring forming step or the contact hole forming step.

### Third Embodiment

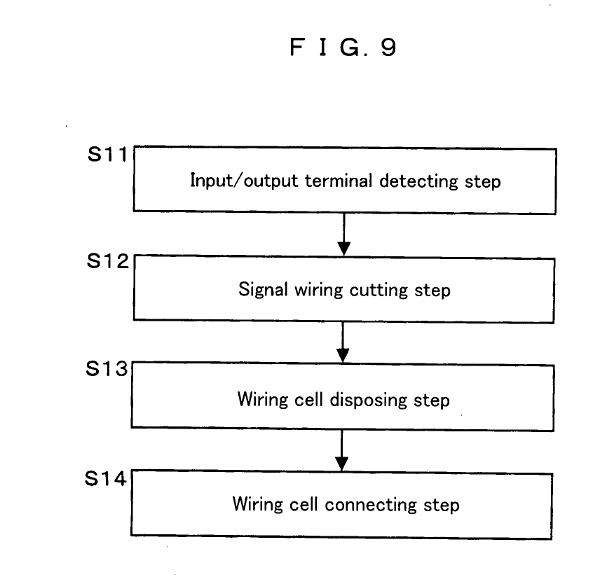

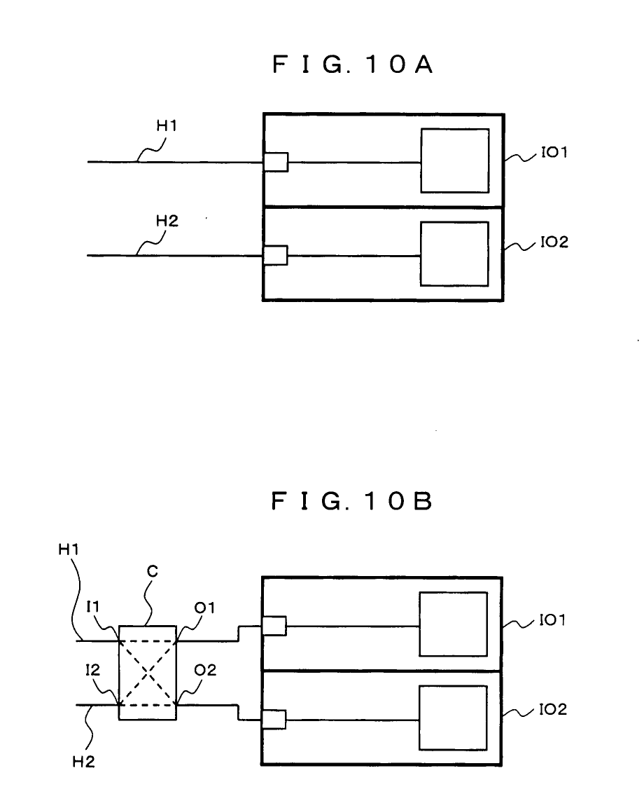

Next, a semiconductor integrated circuit designing method according to a third embodiment of the present invention will be described. FIG. 9 is a flowchart for showing a procedure of the semiconductor integrated circuit designing method according to the third embodiment. FIG. 10A and FIG. 10B are illustrations for showing a specific structure of this embodiment. In FIG. 9, reference numeral S11 is an input/output terminal detecting step, S12 is a signal wiring cutting step, S13 is a wiring cell disposing step, and S14 is a wiring cell connecting step.

First, in the input/output terminal detecting step S11, input/output terminals IO1 and IO2, which may need to be switched due to changes of specifications or the like, are detected from the input/output terminals. Then, in the signal wiring cutting step S12, the input/output terminals IO1, IO2 and the signal wirings H1, H2 which are connected thereto are cut out from each other. Subsequently, in the wiring cell disposing step S13, the variable path wiring cell C is disposed in the vicinity of the input/output terminals IO1 and IO2. Then, in the wiring cell connecting step S14, the signal wirings H1, H2 which were just cut out in the step S12 are connected to the input terminals I1, I2 of the variable path wiring cell C, and the input/output terminals IO1, IO2 are connected to the output terminals O1, O2 of the variable path wiring cell C.

FIG. 10A shows the circuit structure before the variable path wiring cell C is inserted, and FIG. 10B shows the circuit structure after the variable path wiring cell C is inserted. In FIG. 10A and FIG. 10B, reference numerals IO1, IO2 are the input/output terminals, and H1, H2 are the signal wirings.

The variable path wiring cell C is capable of switching the two connection states, i.e. a parallel connection state where the input terminal I1 is connected to the output terminal O1 within the cell, while the input terminal I2 is connected to the output terminal O2 within the cell, and a cross connection state where the input terminal I1 is connected to the output terminal O2 within the cell, while the input terminal I2 is connected to the output terminal O1 within the cell.

Hereinafter, switching of the connection states will be described in detail. First, when the input/output terminals IO1, IO2 are detected, the signal wirings H1, H2 which are connected to the detected input/output terminals IO1, IO2 are cut out from the input/output terminals IO1, IO2. Then, the variable path wiring cell C is disposed in the vicinity of the input/output terminals IO1, IO2. Thereafter, the signal wiring H1 that was just cut out in the above-described step is connected to the input terminal I1 of the variable path wiring cell C, and the signal wiring H2 that was just cut out in the above-described step is connected to the input terminal I2. Finally, the output terminal O1 of the variable path wiring cell C is connected to the input/output terminal IO1, and the output terminal O2 of the variable path wiring cell C is connected to the input/output terminal IO2.

With the use of the variable path wiring cell C that is capable of changing the internal structure, it is possible with the embodiment to switch the two connection states, i.e. a state where the input terminal I1 of the variable path wiring cell C is connected to the input/output terminal IO1, while the input terminal I2 is connected to the input/output terminal IO2 (parallel connection state), and a state where the input terminal I1 of the variable path wiring cell C is connected to the input/output terminal IO2, while the input terminal I2 is connected to the input/output terminal O1 (cross connection state).

Therefore, it is possible to deal with a change in the layout of the input/output terminals IO1, IO2 through changing the internal structure of the variable path wiring cell C. As described above, through applying the variable path wiring cell C to the input/output terminals IO1, IO2 to correct a circuit in the semiconductor integrated circuit, it is possible to achieve a correction of the circuit that is provided between the signal wirings H1, H2 on the first wiring layer and the input/output terminals IO1, IO2 on the second wiring layer by simply correcting one of the masks in any of the forming steps of the first wiring layer, the second wiring layer of the wiring forming step and the contact hole forming step.

The input/output terminals IO1 and IO2 can be replaced with internal pins such as input pins of a hierarchical block. In that case, it becomes possible to deal with a change in a terminal position performed by a change in the circuit within the hierarchy. It is also possible to use the variable path wiring cells C in combination. In that case, it becomes possible to deal with a change in the positions of three or more input/output terminals.

### Fourth Embodiment

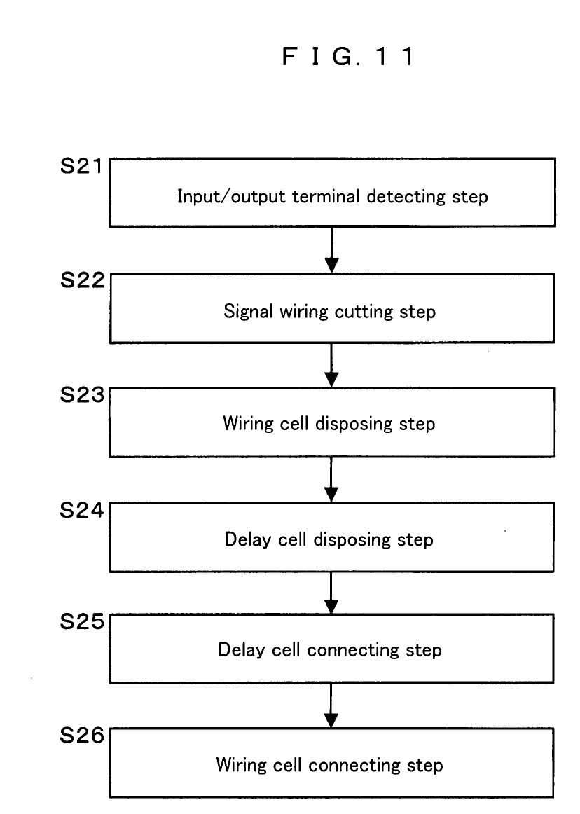

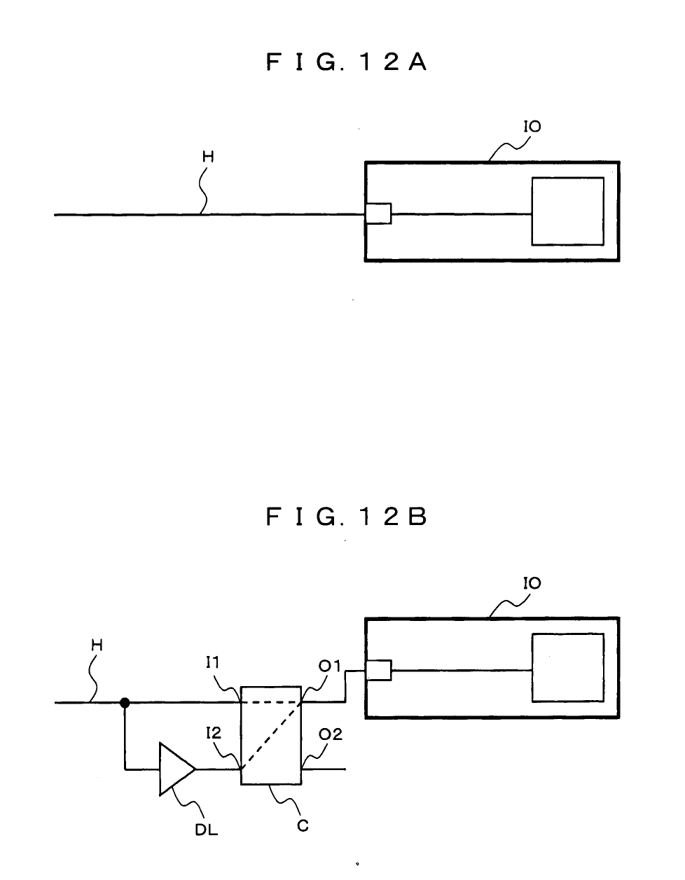

Next, a semiconductor integrated circuit designing method according to a fourth embodiment of the present invention will be described. FIG. 11 is a flowchart for showing a procedure of the semiconductor integrated circuit designing method according to the fourth embodiment. FIG. 12A and FIG. 12B are illustrations for showing an example of a specific structure of this embodiment. In FIG. 11, reference numeral S21 is an input/output terminal detecting step, S22 is a signal wiring cutting step, S23 is a wiring cell disposing step, S24 is a delay cell disposing step, S25 is a delay cell connecting step, and S26 is a wiring cell connecting step.

First, in the input/output terminal detecting step S21, an input/output terminal IO, which may need to be delay-controlled due to changes in the specification or the like, is detected from the input/output terminals. Then, in the signal wiring cutting step S22, the input/output terminal IO and the signal wiring H connected thereto are cut out from each other. Subsequently, in the wiring cell disposing step S23, the variable path wiring cell C is disposed in the vicinity of the input/output terminal IO. Then, in the delay cell disposing step S24, a delay cell DL is disposed in the vicinity of the input/output terminal IO. Thereafter, in the delay cell connecting step S25, the signal wiring H that was just cut out in the step S22 is connected to the input terminal of the delay cell DL. Then, in the wiring cell connecting step S26, the output terminal of the variable path wiring connecting cell C is connected to the input/output terminal IO, and the output terminal of the delay cell DL and the cut out signal wiring H are connected to the input terminals of the variable path wiring cell C.

FIG. 12A shows the circuit structure before the variable path wiring cell C is inserted, and FIG. 12B shows the circuit structure after the variable path wiring cell C is inserted. In FIG. 12A and FIG. 12B, reference symbol DL is the delay cell.

Hereinafter, switching of the connection states will be described in detail. First, when the input/output terminal IO is detected, the signal wiring H which is connected to the detected input/output terminal IO is cut out from the input/output terminal IO. Then, the variable path wiring cell C is disposed in the vicinity of the input/output terminal IO. Thereafter, the delay cell DL is disposed in the vicinity of the input/output terminal IO. Subsequently, the signal wiring H that was just cut out in the above-describe step is connected to the input terminal of the delay cell DL. Then, the signal wiring H that was just cut out in the above-described step is connected to the input terminal I1 of the variable path wiring cell C, and the input terminal I2 of the variable path wiring cell C is connected to the output terminal of the delay cell DL. Finally, the input/output terminal IO is connected to the output terminal O1 of the variable path wiring cell C.

By changing the internal structure of the variable path wiring cell C, it is possible with the embodiment to switch the two connection paths, i.e. a path that does not go through the delay cell DL, and a path that goes through the delay cell DL.

Therefore, even if the output delay value of the input/output terminal IO is changed, it is possible to deal with that change through changing the internal structure of the variable path wiring cell C. Thus, for correcting the circuit in the semiconductor integrated circuit, it is possible to switch the two connection paths, i.e. a path that does not go through the delay cell DL, and a path that goes through the delay cell DL, by changing one of the masks, while applying the variable path wiring cell C and the delay cell DL to the input/output terminal IO, in any of the forming steps of the first wiring layer, the second wiring layer of the wiring forming step and the contact hole forming step.

Further, it is possible with the embodiment to adjust the combinations of the variable path wiring cell C and the delay cell DL. This makes it possible to deal with changes in various delay values.

The delay cell DL may be replaced with an inverter. In that case, it becomes possible to deal with a change in the output logic of the input/output terminal IO. Further, the input/output terminal IO can be replaced with an internal pin such as an input pin of a hierarchy block. In that case, it becomes possible to deal with a change in the delay required due to a change in the circuit within the hierarchy.

### Fifth Embodiment

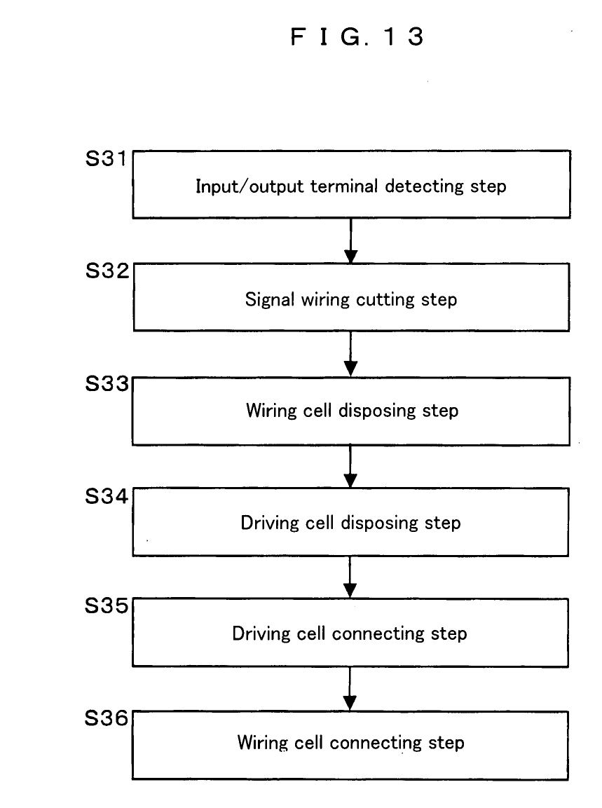

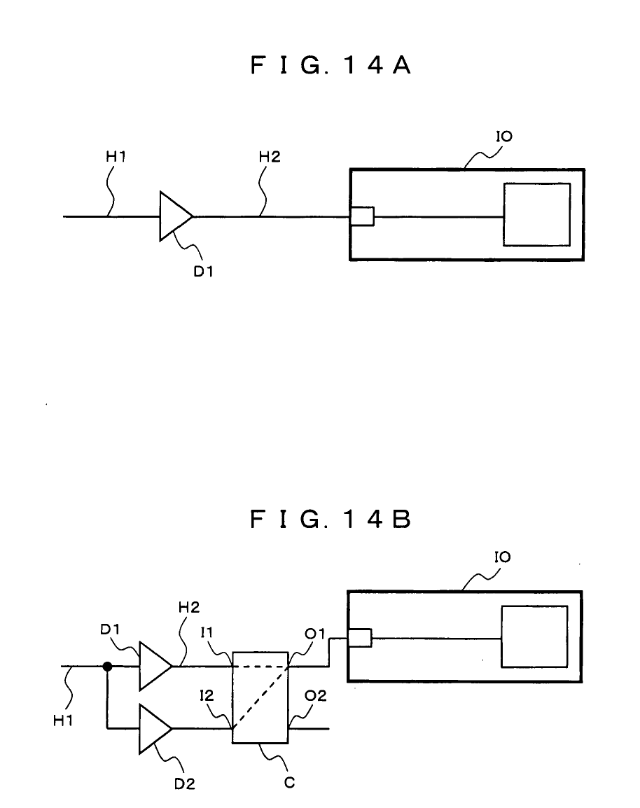

Next, a semiconductor integrated circuit designing method according to a fifth embodiment of the present invention will be described. FIG. 13 is a flowchart for showing a procedure of the semiconductor integrated circuit designing method according to the fifth embodiment. FIG. 14A and FIG. 14B are illustrations for showing an example of a specific structure of this embodiment. In FIG. 13, reference numeral S31 is an input/output terminal detecting step, S32 is a signal wiring cutting step, S33 is a wiring cell disposing step, S34 is a driving cell disposing step, S35 is a driving cell connecting step, and S36 is a wiring cell connecting step.

First, in the input/output terminal detecting step S31, an input/output terminals IO whose driving capacity may need to be controlled due to changes in the specification or the like, is detected from the input/output terminals. Then, in the signal wiring cutting step S32, the input/output terminal IO and the signal wiring H2 connected thereto are cut out from each other. Subsequently, in the wiring cell disposing step S33, the variable path wiring cell C is disposed in the vicinity of the input/output terminal IO. Then, in the driving cell disposing step S34, a driving cell D2 that corresponds to the input/output terminal IO is disposed in the vicinity of the input/output terminal IO, in the same manner as a driving cell D1 that is provided to correspond to the input/output terminal IO. Thereafter, in the driving cell connecting step S35, the signal wiring H1 that supplies signals to the driving cell D1 is connected to the input terminal of the added driving cell D2. Then, in the wiring cell connecting step S36, the input/output terminal IO is connected to the output terminal of O1 of the variable path wiring connecting cell C, the output terminal of the driving cell D1 is connected to the input terminal I1 of the variable path wiring cell C, and the output terminal of the added driving cell D2 is connected to the input terminal I2 of the variable path wiring cell C.

FIG. 14A shows the circuit structure before the variable path wiring cell C is inserted, and FIG. 14B shows the circuit structure after the variable path wiring cell C is inserted. In FIG. 14A and FIG. 14B, reference numerals H1, H2 are the signal wirings, D1 is the driving cell, and D2 is the added driving cell.

First, when the input/output terminal IO is detected, the signal wiring H2 which is connected to the detected input/output terminal IO is cut out from the input/output terminal IO. Then, the variable path wiring cell C is disposed in the vicinity of the input/output terminal IO. Thereafter, the driving cell D2 that corresponds to the input/output terminal IO is disposed in the vicinity of the input/output terminal IO, in the same manner as the driving cell D1 that is provided to correspond to the input/output terminal IO. Subsequently, the signal wiring H1 that supplies signals to the driving cell D1 is connected to the input terminal of the added driving cell D2. Then, the input terminal I1 of the variable path wiring cell C is connected to the output terminal of the driving cell D1, and the input terminal I2 of the variable path wiring cell C is connected to the output terminal of the driving cell D2. Finally, the output terminal O1 of the variable path wiring cell C is connected to the input/output terminal IO.

Through changing the internal structure of the variable path wiring cell C, it is possible with the embodiment to switch the two connection states, i.e. a connection state where only the driving cell D1 is connected to the input/output terminal IO to drive the input/output terminal IO with a single driving cell, and a connection state where the driving cell D1 and the driving cell D2 are connected to the input/output terminal IO to drive the input/output terminal IO with the two driving cells D1, D2.

Therefore, even if the driving capacity required in the input/output terminal IO is changed in the semiconductor integrated circuit, it is possible to switch the two connection states, i.e. a driving state where the input/output terminal is driven only with the driving cell D1, and a driving state where the input/output terminal is driven with the two driving cells D1, D2, through changing one of the masks, while applying the variable path wiring cell C and the driving cell D2 to the input/output terminal, in any of the forming steps of the first wiring layer, the second wiring layer of the wiring forming step and the contact hole forming step.

The input/output terminal IO can be replaced with an internal pin such as an input pin of a hierarchy block. In that case, even if there is a demand for changing the driving capacity based on the change in a circuit within the hierarchy, it becomes possible to deal with that demand.

### Sixth Embodiment

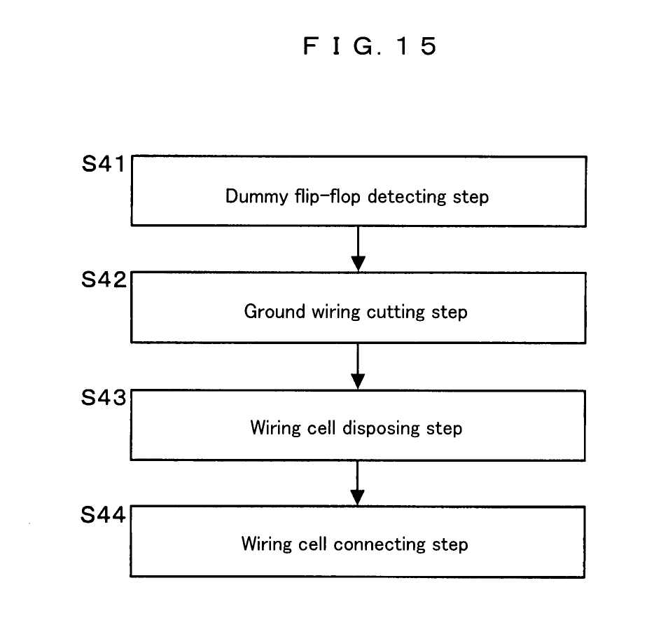

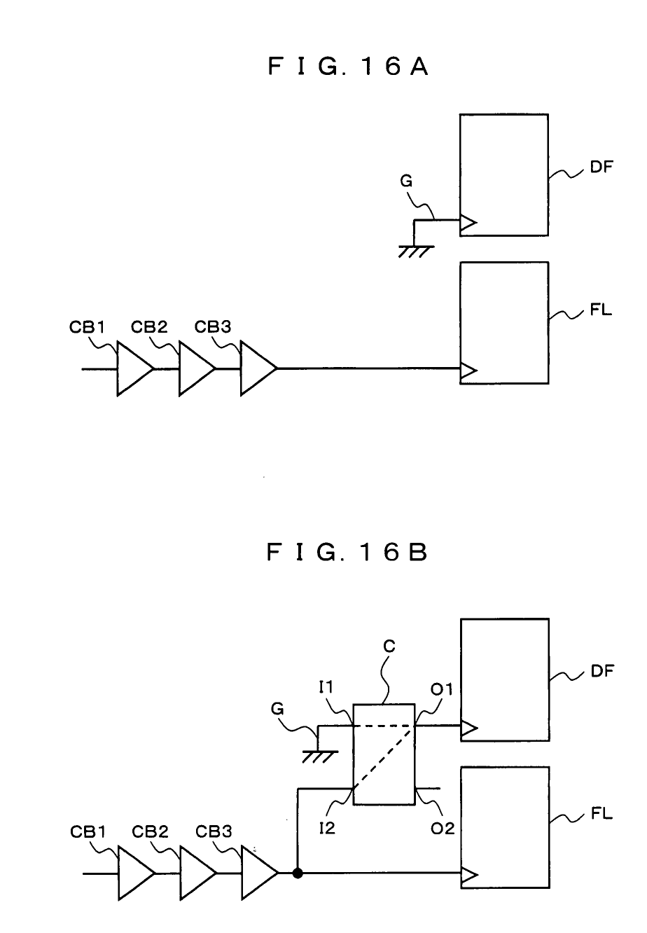

Next, a semiconductor integrated circuit designing method according to a sixth embodiment of the present invention will be described. FIG. 15 is a flowchart for showing a procedure of the semiconductor integrated circuit designing method according to the sixth embodiment. FIG. 16A and FIG. 16B are illustrations for showing an example of a specific structure of a semiconductor integrated circuit fabricated with this embodiment. In FIG. 15, reference numeral S41 is a dummy flip-flop detecting step, S42 is a ground wiring cutting step, S43 is a wiring cell disposing step, and S44 is a wiring cell connecting step.

First, in the dummy flip-flop detecting step S41, a dummy flip-flop DF is detected. Then, in the ground wiring cutting step S42, a clock pin of the dummy flip-flop DF and the ground wiring connected thereto is cut out. Subsequently, in the wiring cell disposing step S43, the variable path wiring cell C is disposed in the vicinity of the dummy flip-flop DF. Then, in the driving cell connecting step S44, the following connecting processing is performed. That is: a terminal on the first wiring layer of the variable path wiring cell C is connected to the clock pin of the dummy flip-flop DF; one of a pair of pins provided on the second wiring layer of the variable path wiring cell C is connected to the ground wiring G; and the other pin provided on the second wiring layer of the variable path wiring cell C is connected to an output terminal of a clock buffer CB3.

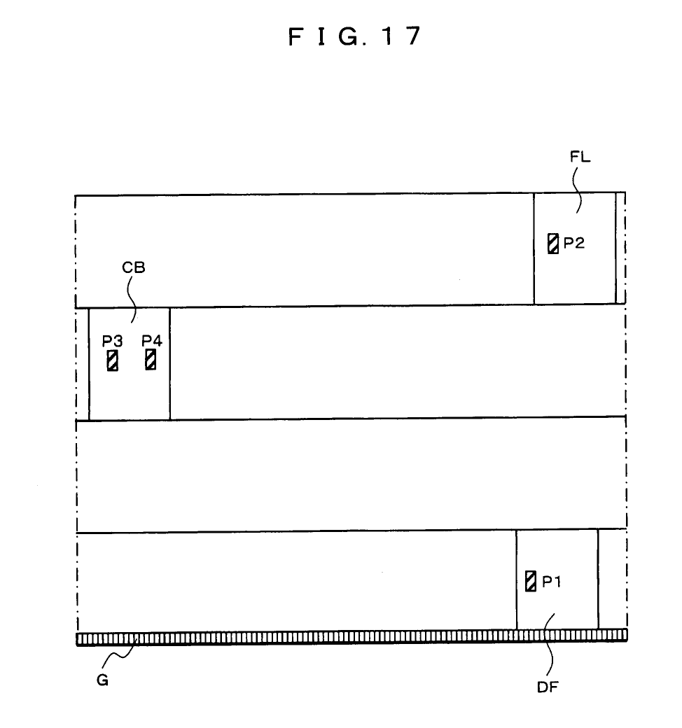

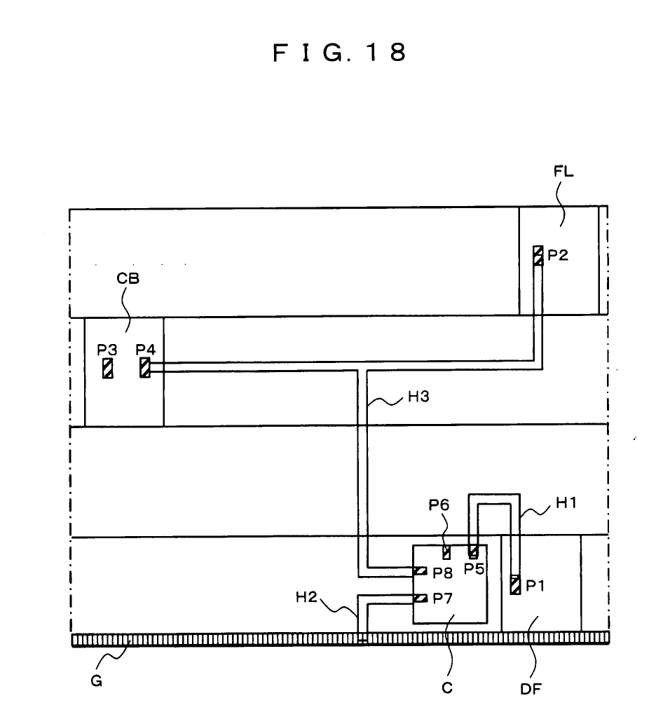

FIG. 16A shows the circuit structure before the variable path wiring cell C is inserted, and FIG. 16B shows the circuit structure after the variable path wiring cell C is inserted. In FIG. 16A and FIG. 16B, reference symbol FL is the flip-flop, DF is the dummy flip-flop, and CB1, CB2, CB3 are the clock buffers. FIG. 17 is a plan view for showing the schematic structure of the semiconductor integrated circuit according to the embodiment before the circuit is corrected, and FIG. 18 is a plan view for showing the schematic structure of the semiconductor integrated circuit according to the embodiment after the circuit is corrected. In FIG. 17, reference symbol DF is the dummy flip-flop that is provided in advance for easily correcting the circuit, FL is the flip-flop, CB is the clock buffer, P1 is a clock pin of the dummy flip-flop DF, P2 is a clock pin of the flip-flop FL, P3 is an input pin of the clock buffer CB, and P4 is an output pin. Further, in FIG. 18, reference symbol C is the variable path wiring cell, P5, P6 are the terminals on the first wiring layer of the variable path wiring cell C, P7, P8 are the pins on the second wiring layer, and H1, H2, H3 are the wirings.

First, when the dummy flip-flop DF is detected, the ground wiring G which is connected to the detected dummy flip-flop DF is cut out therefrom. Then, the variable path wiring cell C is disposed in the vicinity of the dummy flip-flop DF. Thereafter, the cut out ground wiring G is connected to the input terminal I1 of the variable path wiring cell C. Then, the output terminal of the clock buffer CB3 is connected to the input terminal I2 of the variable path wiring cell C. Subsequently, the output terminal O1 of the variable path wiring cell C is connected to the input terminal of the dummy flip-flop DF.

Further, the circuit structure correcting processing according to the embodiment will be described by referring to FIG. 15. First, in the dummy flip-flop detecting step S41, the dummy flip-flop DF is searched. Then, in the ground wiring cutting step S42, information that the ground wiring G is connected to the clock pin of the dummy flip-flop DF is cancelled. Thereafter, in the wiring cell disposing step S43, the variable path wiring cell C is disposed in the vicinity of the clock pin P1 of the dummy flip-flop DF that is detected in the step S41. Subsequently, in the wiring cell connecting step S44, the following are performed. That is: the clock pin P1 of the dummy flip-flop DF and the terminal P5 on the first wiring layer of the variable path wiring cell C are connected via the wiring H1; the terminal P7 on the second wiring layer of the variable path wiring cell C and the ground wiring G are connected via the wiring H2; and the terminal P8 on the second wiring layer of the variable path wiring cell C and the clock pin P2 of the flip-flop FL are connected to the output pin P4 of the clock buffer CB via the wiring H3.

As described above, through changing the internal structure of the variable path wiring cell C, it is possible with the embodiment to switch the following states, i.e. a state where the ground wiring G is connected to the clock pin P1 of the dummy flip-flop DF, and a state where the output pin P4 of the clock buffer CB3 is connected to the clock pin P1. This makes it possible to reduce the change in the delay value of the clock wiring, even when performing such correction in the semiconductor integrated circuit that uses the dummy flip-flop.

### Seventh Embodiment

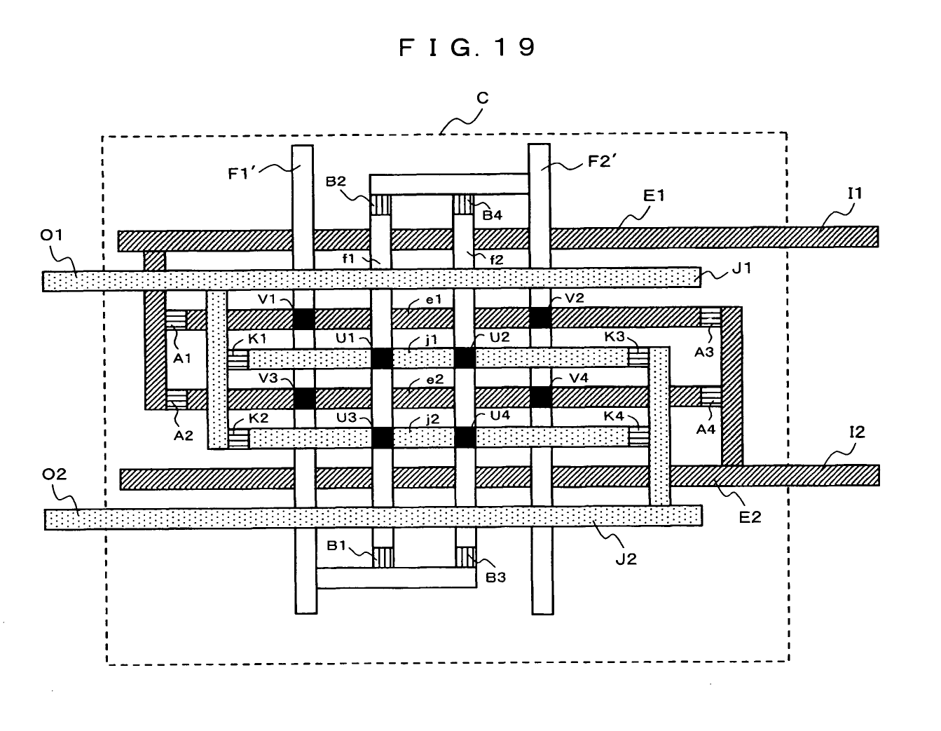

Next, a semiconductor integrated circuit designing method according to a seventh embodiment of the present invention will be described. FIG. 19 is a layout top plan view for showing the structure of a variable path wiring cell C that is constituted with wiring layers from the m-th layer to the n-th layer, where m and n are natural numbers (m−n≧2). Even though FIG. 19 shows an example of the case with three layers, it is also possible to build a variable path wiring cell C with more than three layers in the same structure described below.

It should be noted here that the first externally extended wiring E1 and the second externally extended wiring E2 on the first wiring layer can be electrically connected to the first internally present wiring e1 and the second internally present wiring e2 on the same wiring layer within the variable path wiring cell C through forming a wiring pattern in the wiring areas A1-A4.

Further, a first outer-side wiring F1′ and a second outer-side wiring F2′ on the second wiring layer can be electrically connected to the first internally present wiring f1 and the second externally present wiring f2 on the same wiring layer through forming a wiring pattern in the wiring areas B1-B4.

Further, the first internally present wiring e1, the second internally present wiring e2, the first outer-side wiring F1′, and the second outer-side wiring F2′ can be electrically connected to one another through the contact wiring areas V1-V4 which connect the first wiring layer and the second wiring layer.

The above-described structure is the same as that of the first embodiment shown in FIG. 2. However, the seventh embodiment is different from the first embodiment in respect that the outer-side wirings F1′, F2′ having no externally extended part are provided in the seventh embodiment whereas the externally extended wirings F1, F2 are provided in the first embodiment (FIG. 2). In addition, the seventh embodiment is different from the first embodiment in respect that a first externally extended wiring J1 and a second externally extended wiring J2 on the third wiring layer can be electrically connected to a first internally present wiring j1 and a second internally present wiring j2 on the same wiring layer through forming a wiring pattern in wiring areas K1-K4. Further, according to the seventh embodiment, the internally present wiring f1 on the second wiring layer can be electrically connected to the first internally present wiring j1 and the second internally present wiring j2 on the third wiring layer via wiring areas U1, U3 of the contact which connects the second wiring layer and the second wiring layer. Further, the internally present wiring f2 on the second wiring layer can be electrically connected to the first internally present wiring j1 and the second internally present wiring j2 on the third wiring layer via wiring areas U2, U4 of the contact.

As shown in FIG. 19, in the case where three or more layers of wiring patterns are stacked, it is necessary to connect the T-shaped wiring and the wiring on the inner side through a contact hole for the wiring pattern on the k-th (m≦k≦n−1) layer, as shown in the contact wiring areas V1, V2, V3, and V4 which connect the first internally present wiring e1, the second internally present wiring e2, the first outer-side wiring F1′, and the second outer-side wiring F2′.

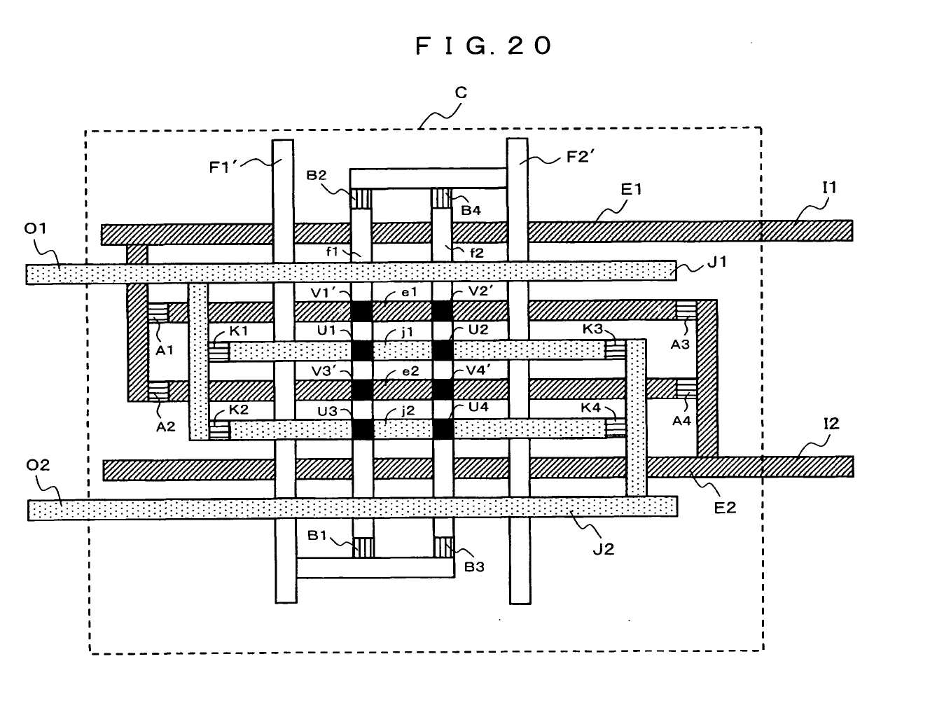

On the other hand, as shown in FIG. 20, in the case where contact wiring areas V1′, V2′, V3′, V4′ whose positions are shifted with respect to the wiring areas V1, V2, V3, V4 are provided, it is not possible to change the connecting relation of the input terminals and the output terminals with the wiring pattern on the k-th layer.

In the case where the externally extended wirings (outer-side wirings) are connected to each other through the contact hole, it is also not possible to change the connecting relation of the input terminals and the output terminals with the wiring pattern on the k-th layer as in the above-described case. When the input terminal I1 is connected to the output terminal O1, and the input terminal I2 is connected to the output terminal O2, the connection patterns are (I1-E1-A1-e1-V1-F1′-B1-f1-U1-j1-K1-J1-O1), and (I2-E2-A4-e2-V4-F2′-B4-f2-U4-j2-K4-J2-O2).

Instead of the above, when the input terminal I1 is connected to the output terminal O2, and the input terminal I2 is connected to the output terminal O1, the connection patterns become as follows. That is, when the connecting relations are changed on the first wiring layer, the connection patterns are (I1-E1-A2-e2-V4-F2′-B4-f2-U4-j2-K4-J2-O2), and (I2-E2-A3-e1-V1-F1′-B1-f1-U1-j1-K1-J1-O1).

Further, when the connecting relations are changed on the interlayer contact layer between the first wiring layer and the second wiring layer, the connection patterns are (I1-E1-A1-e1-V2-F2′-B4-f2-U4-j2-K4-J2-O2), and (I2-E2-A4-e2-V3-F1′-B1-f1-U1-j1-K1-J1-O1).

Further, when the connecting relations are changed on the second wiring layer, the connection patterns are (I1-E1-A1-e1-V1-F1′-B3-f2-U4-j2-K4-J2-O2), and (I2-E2-A4-e2-V4-F2′-B2-f1-U1-j1-K1-J1-O1).

When the connecting relations are changed on the interlayer contact layer between the second wiring layer and the third wiring layer, the connection patterns are (I1-E1-A1-e1-V1-F1′-B1-f1-U3-j2-K4-J2-O2), and (I2-E2-A4-e2-V4-F2′-B4-f2-U2-j1-K1-J1-O1).

When the connecting relations are changed on the third wiring layer, the connection patterns are (I1-E1-A1-e1-V1-F1′-B1-f1-U1-j1-K3-J2-O2), and (I2-E2-A4-e2-V4-F2′-B4-f2-U4-j2-K2-J1-O1).

Through employing the structures described above, the variable path wiring cell C described by referring to FIG. 2-FIG. 5 can be constituted with three or more layers of wiring layers.

The present invention has been described in detail by referring to the most preferred embodiments. However, various combinations and modifications of the components are possible without departing from the spirit and the broad scope of the appended claims.

What is claimed is:

1. A variable path wiring cell, comprising:
a first wiring layer which comprises a first and a second internally present wirings provided inside said cell as well as a first and a second externally extended wirings that are provided with an internally present part within said cell and an externally extended part extending towards an outer side of said cell, wherein each of said first and second internally present wirings can be selectively connected to said first and second externally extended wirings;
a second wiring layer which comprises substantially the same first and second internally present wirings and substantially the same first and second externally extended wirings as those of said first wiring layer, while having a different wiring longitudinal direction from that of said first wiring layer and being disposed in a manner opposite to said first wiring layer; and
an interlayer contact layer which arbitrarily connects one of said first, second internally present wirings on said first wiring layer to one of said first, second internally present wirings on said second wiring layer, and connects a remainder of said first, second internally present wirings on said first wiring layer to the remainder of said first, second internally present wirings on said second wiring layer.

2. A semiconductor integrated circuit, comprising:
a version code register; and
said variable path wiring cell of claim 1, wherein
there are a plurality of said variable path wiring cells being provided, and said variable path wiring cells are connected to said version code register.

3. A semiconductor integrated circuit designing method which applies said variable path wiring cell of claim 1 to a dummy cell that is disposed within a semiconductor integrated circuit, said method comprising:
a step of detecting said dummy cell;
a step of disposing said variable path wiring cell in a vicinity of said dummy cell; and
a step of connecting said variable path wiring cell to said dummy cell.

4. A semiconductor integrated circuit designing method which applies said variable path wiring cell of claim 1 to an input/output terminal, said method comprising:
a step of detecting said input/output terminal;
a step of cutting a connection between said input/output terminal and a signal wiring that is connected to said input/output terminal;
a step of disposing said variable path wiring cell in a vicinity of said input/output terminal; and
a step of connecting said input/output terminal to said cut out signal wiring via said variable path wiring cell.

5. A semiconductor integrated circuit designing method which applies said variable path wiring cell of claim 1 to an input/output terminal and a delay cell, said method comprising:
a step of detecting said input/output terminal;
a step of cutting a connection between said input/output terminal and a signal wiring that is connected to said input/output terminal;
a step of disposing said variable path wiring cell and said delay cell in the vicinity of said input/output terminal;
a step of connecting said cut out signal wiring to an input terminal of said delay cell; and
a step of connecting said variable path wring cell to said input/output terminal and an output terminal of said delay cell.

6. A semiconductor integrated circuit designing method which applies said variable path wiring cell of claim 1 to an input/output terminal and a driving cell, said method comprising:
a step of detecting said input/output terminal;
a step of cutting a connection between said input/output terminal and a signal wiring that is connected to said input/output terminal;
a step of disposing said variable path wiring cell and said driving cell in the vicinity of said input/output terminal; and
a step of connecting said cut out signal wiring to an input terminal of said driving cell; and
a step of connecting said variable path wiring cell to said input/output terminal and an output terminal of said driving cell.

7. A semiconductor integrated circuit designing method which applies said variable path wiring cell of claim 1 having a pair of terminals to a dummy flip-flop having a clock terminal, said method comprising:
a step of detecting said dummy flip-flop;
a step of disposing said variable path wiring cell in the vicinity of said dummy flip-flop;
a step of connecting said variable path wiring cell to said clock terminal; and
a step of connecting one of said terminals of said variable path wiring cell to a power supply or a ground.

8. A variable path wiring cell forming method, comprising:
a step of forming a k-th wiring layer (m≦k≦n−1, where m and n are integers of 1 or larger (n−m≧2)), which comprises a first and a second internally present wirings provided inside said cell as well as a first and a second externally extended wirings that are provided with an internally present part within said cell and an externally extended part extending towards an outer side of said cell, wherein each of said first and second internally present wirings can be selectively connected to said first and second externally extended wirings;
a step of forming a (k+1)th wiring layer which comprises substantially the same first and second internally present wirings and the substantially the same first and second externally extended wirings as those of said k-th wiring layer, while having a different wiring longitudinal direction from that of said k-th wiring layer and being disposed in a manner opposite to said k-th wiring layer;
a step of forming an interlayer contact layer which arbitrarily connects one of said first, second internally present wirings on said k-th wiring layer to one of said first, second internally present wirings on said (k+1)th wiring layer, and connect the remainder of said first, second internally present wirings on said k-th wiring layer to the remainder of said first, second internally present wirings on said (k+1)th layer; and
a step of repeating said steps described above to a (n−1)th layer by replacing “k” with “(k+1)”.
